(19) United States
(12) Patent Application Publication
(10) Pub. No.: US 2021/0028332 A1
(43) Pub. Date: Jan. 28, 2021

(54) OPTICAL DEVICE AND METHOD OF FORMING THE SAME

(71) Applicants: Agency for Science, Technology and Research, Singapore (SG); Nanyang Technological University, Singapore (SG)

(72) Inventors: Zhengtong Liu, Singapore (SG); Yuriy Akimov, Singapore (SG); Song Sun, Singapore (SG); Egor Khaidarov, Singapore (SG); Ramon Paniagua Dominguez, Singapore (SG); Arseniy Kuznetsov, Singapore (SG); Hilmi Volkan Demir, Singapore (SG)

(21) Appl. No.: 16/766,936

(22) PCT Filed: Dec. 20, 2018
(86) PCT No.: PCT/SG2018/050624

§ 371 Date: May 26, 2020

(30) Foreign Application Priority Data
Dec. 21, 2017 (SG) 10201710683Y

(51) Int. Cl. H01L 33/46; G02B 27/30; H01L 27/15; G02B 1/00; G02B 26/08

(52) U.S. Cl. CPC H01L 33/465; G02B 27/30; G02B 26/0816; G02B 1/005; H01L 27/15

(57) ABSTRACT

Various embodiments may relate to an optical device. The optical device may include a radiation collimator configured to generate a directed light beam based on omni-directional light emission. The optical device may also include one or more optical elements configured to change a parameter of the directed light beam. The radiation collimator comprises a first reflector, a second reflector and a spacer between the first reflector and the second reflector. The first reflector, the second reflector and the spacer form a resonant cavity.

### CROSS-REFERENCE TO RELATED APPLICATION

This application claims the benefit of priority of Singapore application No. 10201710683Y filed Dec. 21, 2017, the contents of it being hereby incorporated by reference in its entirety for all purposes.

### TECHNICAL FIELD

Various aspects of this disclosure relate to an optical device. Various aspects of this disclosure relate to a method of forming an optical device.

### BACKGROUND

Traditional optical elements such as lenses, polarizers, and holograms rely on refractive optics principles, where light can be manipulated over distances much longer than optical wavelengths. As a result, traditional optical elements are bulky and heavy.

On the other hand, flat optics or diffractive optics enable light to be efficiently manipulated over wavelength-scale distances. Flat optics or diffractive optics have been extensively studied from the early 1990s. Even before that, non-resonant dielectric or metallic inclusions have been used in binary blazed gratings, which allow control of the amplitude, phase and/or polarization of an impinging optical beam.

Researchers have showed that flat optics or diffractive optics can achieve different functionalities (such as beam bending surfaces or flat lenses) with remarkable efficiencies that may reach values above 80%. The main limitation of this approach is the large aspect ratio of the structures involved, which strongly limits their fabrication using large-scale techniques such as nano-imprint. A more recent approach that allows creation of very compact optical elements (with aspect ratios significantly smaller) is based on light interaction with arrays of resonant subwavelength inclusions, so called nanoantennas, that are arranged in an array forming metasurfaces. The metasurfaces have different designs depending on their functionalities. They have been successfully employed to produce different devices, ranging from polarizers, lenses and axicon generators to holography masks, optical vortex generators, and many more. FIG. 1A shows images of a metasurface acting as a flat lens. FIG. 1B shows images of a metasurface forming an optical vortex. FIG. 1C shows a metasurface for holography.

The metasurface designs have been proven to be efficient in manipulating light of different polarizations over wavelength-scale distances. However, these metasurfaces are designed for plane waves, or for point emitters (molecules, fluorophores, etc.) in which the precise positions are known. In other situations, the metasurfaces may not work, or the efficiency drops significantly. As such, conventional metasurfaces may be unable or may not be efficient in manipulating omni-directional light generated by random emitters such as light-emitting diodes (LEDs), quantum dots, or fluorescence dye aggregates, etc. FIG. 1D shows a schematic of a light-emitting device.

### SUMMARY

Various embodiments may relate to an optical device. The optical device may include a radiation collimator configured to generate a directed light beam based on omni-directional light emission. The optical device may also include one or more optical elements configured to change a parameter of the directed light beam.

Various embodiments may relate to a method of forming an optical device. The method may include forming a radiation collimator configured to generate a directed light beam based on omni-directional light emission. The method may also include forming one or more optical elements configured to change a parameter of the directed light beam.

### BRIEF DESCRIPTION OF THE DRAWINGS

The invention will be better understood with reference to the detailed description when considered in conjunction with the non-limiting examples and the accompanying drawings, in which:

FIG. 1A shows images of a metasurface acting as a flat lens.

FIG. 1B shows images of a metasurface forming an optical vortex.

FIG. 1C shows a metasurface for holography.

FIG. 1D shows a schematic of a light-emitting device.

FIG. 1E shows a schematic of an integrated device including a metasurface and a light emitting device.

FIG. 1F shows emission patterns of the integrated device shown in FIG. 1E.

FIG. 2 is a general illustration of an optical device according to various embodiments.

FIG. 3 is a general illustration of a method of forming an optical device according to various embodiments.

FIG. 4 is a schematic showing a cross-sectional side view of an optical device according to various embodiments.

FIG. 5A is a schematic showing a cross-sectional side view of one supercell of an optical device according to various embodiments.

FIG. 5B is a schematic showing a top planar view of the supercell of the optical device shown in FIG. 5A according to various embodiments.

FIG. 5C shows the emission pattern of the active layer embedded in the bare spacer (i.e. without reflectors and metasurface).

FIG. 5D shows the emission pattern of the resonant cavity, which include the front reflector, the back reflector, and the spacer with the embedded active layer of the optical device (i.e. without metasurface) according to various embodiments.

FIG. 6A is a schematic showing a resonant cavity without metasurface according to various embodiments.

FIG. 6B shows emission pattern of the active layer (i.e. without reflectors and metasurface).

FIG. 6C shows a possible emission pattern of the resonant cavity without metasurface according to various embodiments.

FIG. 6D shows another possible emission pattern of the resonant cavity without metasurface according to various embodiments.

FIG. 6E shows yet another possible emission pattern of the resonant cavity without metasurface according to various embodiments.

FIG. 7A is a schematic showing a resonant cavity without metasurface according to various embodiments.

FIG. 7B shows a possible emission pattern of the resonant cavity without metasurface according to various embodiments.

FIG. 7C shows another possible emission pattern of the resonant cavity without metasurface according to various embodiments.

FIG. 8A is a schematic showing a perspective view of a metasurface supercell including 8 titanium oxide (TiO₂) cylinders of the optical device according to various embodiments.

FIG. 8B shows the emission pattern of an optical device without a metasurface according to various embodiments.

FIG. 8C shows the emission pattern of an optical device having the metasurface with a supercell of 8 cylinders as shown in FIG. 8A according to various embodiments.

FIG. 8D shows the emission pattern shown in FIG. 8C of the optical device according to various embodiments compared to the cavity emission pattern (rotated by 10°).

FIG. 8E shows the emission pattern of the optical device having the supercell as shown in FIG. 8A according to various embodiments in a plane perpendicular to the supercell.

FIG. 9A is a schematic showing a perspective view of a metasurface super cell including 4 titanium oxide (TiO₂) cylinders of the optical device according to various embodiments.

FIG. 9B shows the emission pattern of an optical device having the metasurface with a supercell of 4 cylinders as shown in FIG. 9A according to various embodiments.

FIG. 9C shows the emission pattern shown in FIG. 9B of the optical device according to various embodiments compared to the cavity emission pattern (rotated by 19°).

FIG. 9D shows the emission pattern of the optical device having the supercell as shown in FIG. 9A according to various embodiments in a plane perpendicular to the super cell.

FIG. 9E shows a three dimensional emission pattern of the optical device having a supercell as shown in FIG. 9A.

FIG. 10A is a schematic showing a cross-sectional side view of an optical device according to various embodiments.

FIG. 10B shows the emission pattern of the optical device as shown in FIG. 10A in which the top reflector is 10 nm thick according to various embodiments.

FIG. 10C shows the emission pattern of the optical device as shown in FIG. 10A in which the top reflector is 20 nm thick according to various embodiments.

FIG. 10D shows the emission pattern of an optical device with a Bragg reflector as the top reflector according to various embodiments.

FIG. 11A is a schematic showing a cross-sectional side view of an optical device according to various embodiments.

FIG. 11B shows an emission pattern of an optical device without the phase compensating region according to various embodiments.

FIG. 11C shows an emission pattern of the optical device including the phase compensating region 1114 as shown in FIG. 11A according to various embodiments.

FIG. 11D shows another emission pattern of the device including the phase compensating region 1114 as shown in FIG. 11A according to various embodiments.

FIG. 11E shows yet another emission pattern of the device including the phase compensating region 1114 as shown in FIG. 11A according to various embodiments.

FIG. 11F shows yet another emission pattern of the device including the phase compensating region 1114 as shown in FIG. 11A according to various embodiments.

FIG. 12A is a schematic showing a cross-sectional side view of an optical device according to various embodiments.

FIG. 12B is a diagram comparing the total emitted power of a light emitting diode (LED), a cavity light emitting diode (LED), and an optical device as shown in FIG. 12A according to various embodiments.

FIG. 13A is a schematic showing a cross-sectional side view of an optical device according to various embodiments.

FIG. 13B is a schematic showing a top planar view of the optical device shown in FIG. 13A according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or optical devices are analogously valid for the other methods or optical devices. Similarly, embodiments described in the context of a method are analogously valid for an optical device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

A metasurface may be a textured surface with sub-wavelength scale and/or wavelength scale structures and may be used to control electromagnetic radiation. As opposed to conventional optical elements which are typically bulky, heavy, and fixed, a metasurface may be thin, light, and tunable.

A metasurface may be integrated with light sources. However, as highlighted above, conventional metasurfaces may be designed for plane waves and point emitters, and may not work well with random emitters like light-emitting devices or diodes.

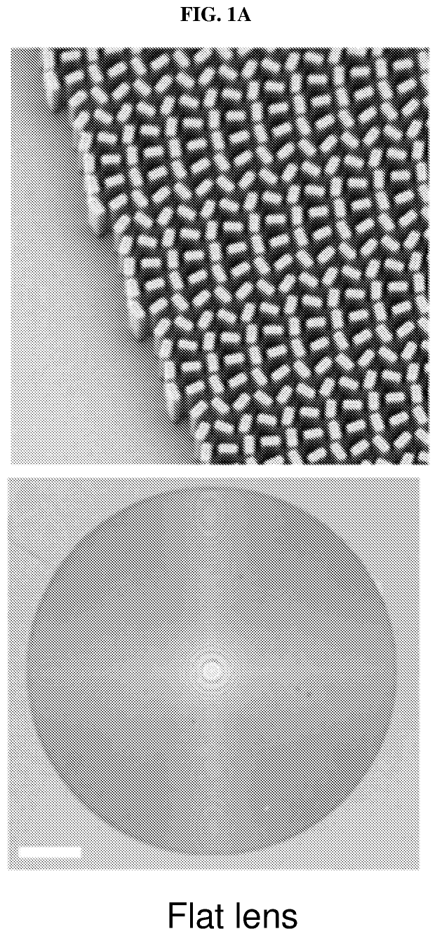

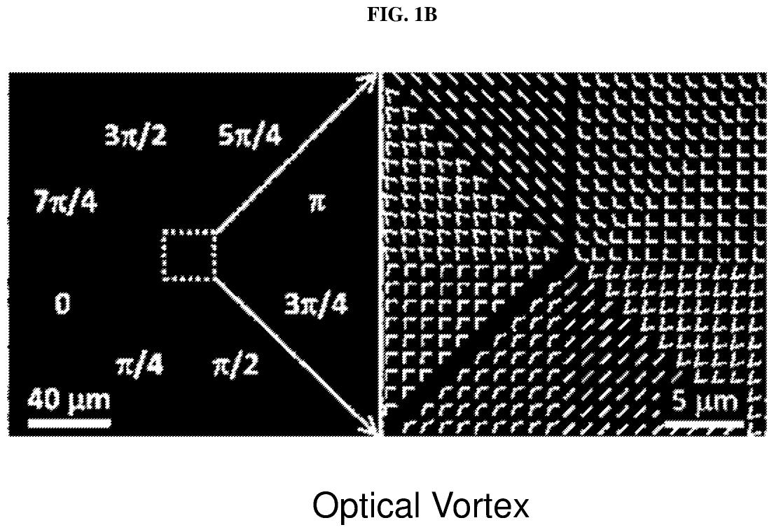

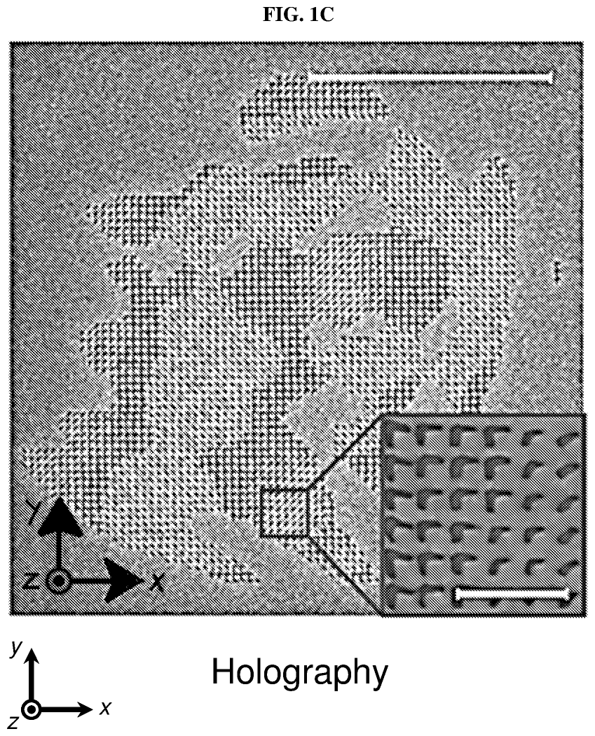

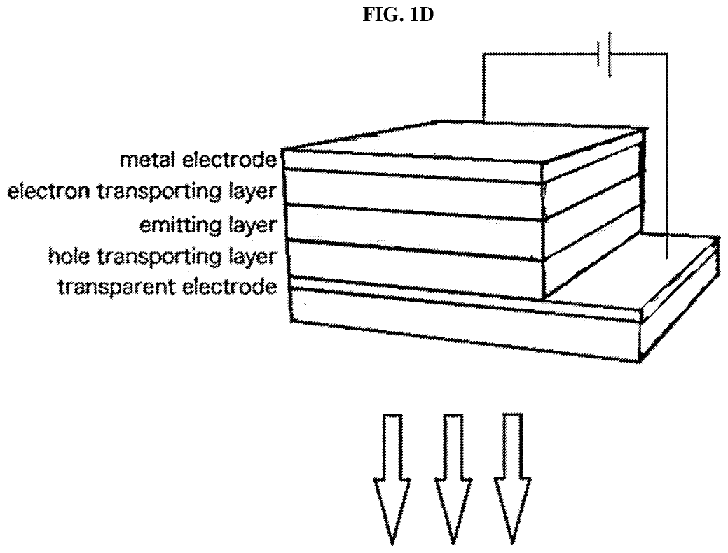

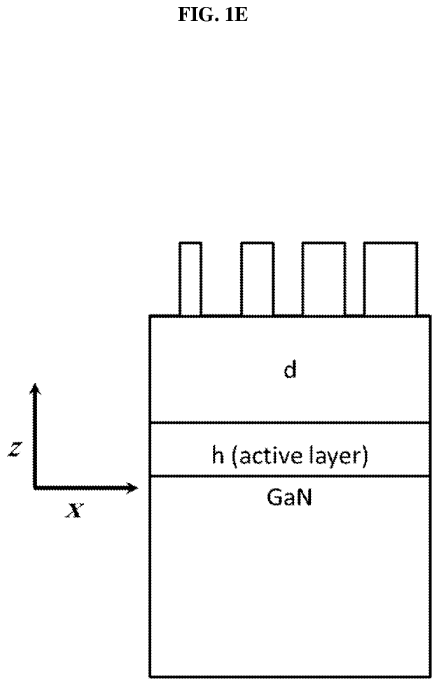

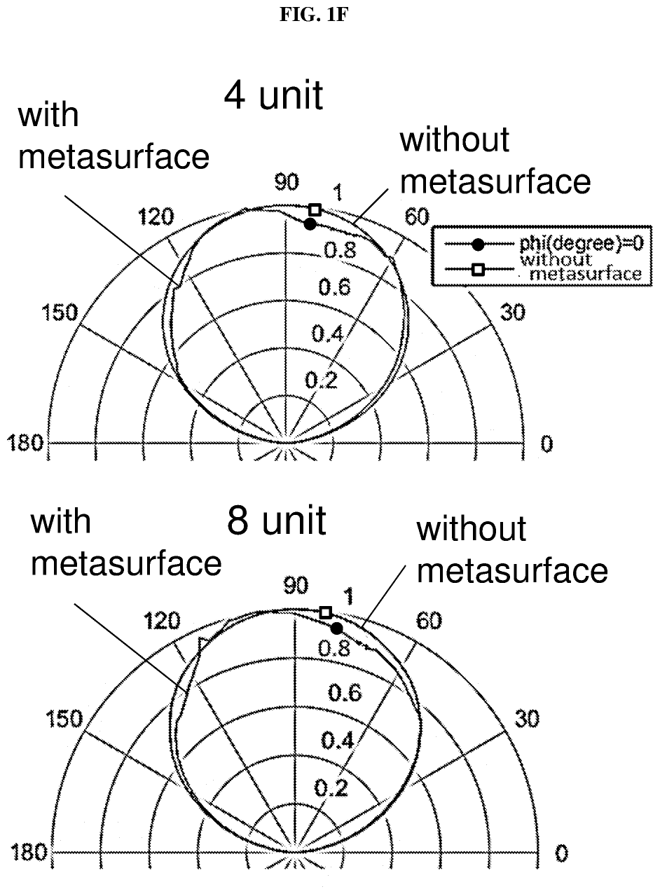

FIG. 1E shows a schematic of an integrated device including a metasurface and a light emitting device. FIG. 1F shows emission patterns of the integrated device shown in FIG. 1E.

Various embodiments may seek to address the abovementioned issues facing conventional optical elements or conventional metasurfaces.

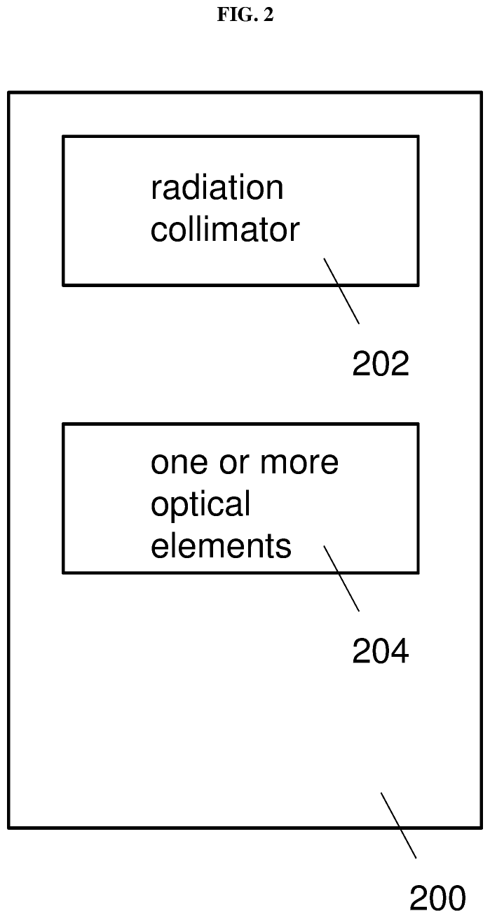

FIG. 2 is a general illustration of an optical device 200 according to various embodiments. The optical device 200 may include a radiation collimator 202 configured to generate a directed light beam based on omni-directional light emission. The optical device 200 may also include one or more optical elements 204 configured to change a parameter of the directed light beam.

In other words, the optical device 200 may include a radiation collimator 202 to collimate omni-directional light emission into a collimated or directed light beam so that the one or more optical elements 204 may further manipulate the collimated or directed light beam.

For avoidance of doubt, FIG. 2 merely serves to illustrate the features of an optical device 200 according to various embodiments, and does not limit, for instance, the relative positions, orientations, shapes, or sizes of the features.

An omni-directional light emission is light emitted by one or more light sources in all random directions. A directed light beam is a highly directional light beam, i.e. light rays which travel substantially in a single direction, or along a narrow range of directions, e.g. within 30°, e.g. within 20°, e.g. within 15° or 10°, from one another.

In various embodiments, the optical device 200 may include an optical coupler configured to couple the directed light beam to the one or more optical elements 204. In various other embodiments, the optical device 200 may be devoid of an optical coupler. The optical coupler may be configured to adjust a phase of the directed light beam. In various embodiments, the optical coupler may be or may include a phase compensating layer or region.

In various embodiments, the radiation collimator 202 may include a first reflector, a second reflector, and a spacer between the first reflector and the second reflector;

In various embodiments, the first reflector, the second reflector, and the spacer may form a cavity, i.e. resonant cavity.

In various embodiments, the first reflector, the spacer, the second reflector, the one or more optical elements, and optionally the optical coupler may form a vertical stacked arrangement. The spacer may be on or over the second reflector. The first reflector may be on or over the spacer. The optical coupler may be on or over the first reflector. The one or more optical elements 204 may be on or over the optical coupler, or on or over the first reflector.

The first reflector and the second reflector may be used to establish a strong resonance inside the resonant cavity.

The second reflector may be more reflective compared to the first reflector.

In various embodiments, the first reflector may be partially reflective. The first reflector may be configured to allow at least a portion of the directed light beam to pass through to the one or more optical elements. The first reflector may be or may include a Bragg grating, or a plurality of Bragg gratings.

In various embodiments, the second reflector may be fully reflective. The second reflector may be configured to reflect all or almost all of the light impinging on the second reflector. The second reflector may be or may include a metal reflector, such as an aluminum reflector. In various other embodiments, the second reflector may be a Bragg grating.

For instance, the second reflector may have a reflectance having a percentage value above 95%, or above 99%, or at 100%, while the first reflector may have a reflectance having a percentage value selected from a range between 30% to 70%, or between 40% to 60%. However, it may be envisioned that the first reflector or the second reflector may have any suitable reflectance value. For instance, the second reflector may have a reflectance value above 90%.

The spacer may include a semiconductor (e.g. silicon (Si) or a III-V semiconductor such as gallium nitride (GaN), gallium phosphide (GaP), gallium arsenide (GaAs), or indium phosphide (InP)), or a dielectric. The first reflector and/or the second reflector may have a refractive index higher than the spacer.

In various embodiments, the optical device may also include one or more light emitters configured to generate the omni-directional light emission. In various embodiments, the one or more light emitters may be within the spacer. In various other embodiments, the one or more light emitters may be outside of the spacer. In various embodiments, the light emission may be of any suitable wavelength or range of wavelengths. In various embodiments, the light emission may refer to emission of visible light, i.e. light having a wavelength or range of wavelengths selected from 390 nm to 700 nm. In various other embodiments, the light emission may also refer to infrared light and ultraviolet light in addition to visible light. The light may have a wavelength or range of wavelengths selected from 100 nm to 100 μm.

In various embodiments, the one or more optical elements may form a metasurface. The one or more optical elements may be microstructures or nanostructures. The one or more optical elements may be sub-wavelength scale or wavelength scale structures. In other words, one or more dimension of each optical element may be less than the wavelength or range of wavelengths of the light emitted by the one or more light emitters. In various other embodiments, the one or more optical elements may be super-wavelength structures. In other words, all dimensions of each optical element may be greater than the wavelength or range of wavelengths of the light emitted by the one or more light emitters.

In various embodiments, the one or more optical elements may be resonant elements. In various other embodiments, the one or more optical elements may be non-resonant elements.

The one or more optical elements may be or may include a blazed or echelette grating, a binary blazed grating, an asymmetric diffractive grating, or a phased array antenna. The phase array antenna may include metallic and/or dielectric elements.

In various embodiments, the one or more optical elements may have the same dimensions. In various embodiments, the one or more optical elements may have different dimensions, for instance different widths. A dimension, e.g. a width, of a first optical element of the one or more optical elements may be different from a dimension, e.g. a width, of a second optical element of the one or more optical elements.

In various embodiments, the one or more optical elements 204 may be configured to change a direction of the directed light beam (e.g. to steer or focus the directed light beam), an amplitude of the directed light beam, a phase of the directed light beam, or to change a polarization of the directed light beam (e.g. to polarize an initially non-polarized directed light beam).

In various embodiments, the parameter of the directed light beam may be a direction of the directed light beam. In various other embodiments, the parameter of the directed light beam may be an amplitude of the directed light beam. In yet various other embodiments, the parameter of the directed light beam may be a phase of the directed light beam. In yet various other embodiments, the parameter of the directed light beam may be a polarization of the directed light beam.

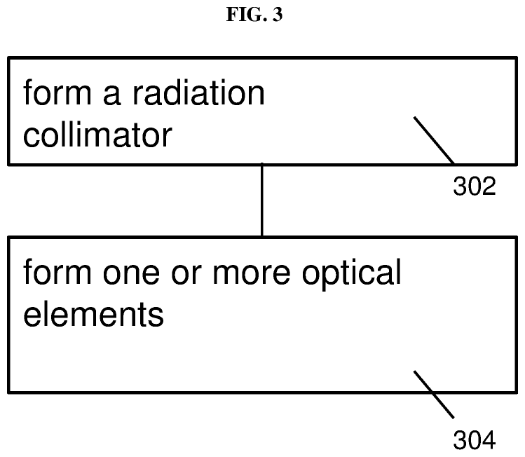

FIG. 3 is a general illustration of a method of forming an optical device according to various embodiments. The method may include, in 302, forming a radiation collimator configured to generate a directed light beam based on omni-directional light emission. The method may also include, in 304, forming one or more optical elements configured to change a parameter of the directed light beam.

In other words, the method may include forming a device including a radiation collimator and one or more optical elements.

For avoidance of doubt, the steps shown in FIG. 3 are not intended to be in sequence. Step 302 may occur before, after, or at the same time as step 304.

In various embodiments, the method may further include forming an optical coupler configured to couple the directed light beam to the one or more optical elements.

In various embodiments, the optical coupler may be further configured to adjust a phase of the directed light beam.

In various embodiments, the radiation collimator may include a first reflector, a second reflector, and a spacer between the first reflector and the second reflector. The first reflector, the second reflector, and the spacer may form a resonant cavity. In various embodiments, the method may include forming the second reflector on or over a substrate, forming a spacer on or over the second reflector, and forming the first reflector on or over the spacer. The optical coupler may be formed on or over the first reflector. The one or more optical elements may be formed on or over the optical coupler, or on or over the first reflector.

The method may additionally include forming or providing one or more light emitters configured to generate the omni-directional light emission. In various embodiments, the one or more light emitters may be formed or provided within the spacer. In various other embodiments, the one or more light emitters may be formed or provided outside of the spacer.

In various embodiments, the one or more optical elements may form a metasurface.

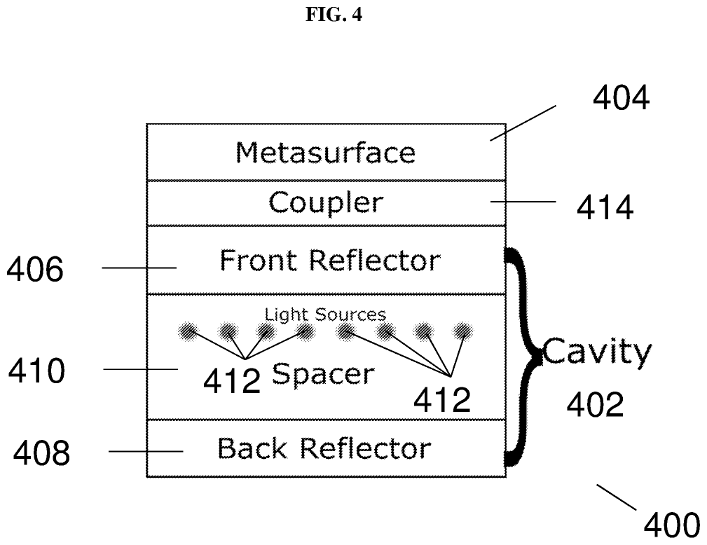

FIG. 4 is a schematic showing a cross-sectional side view of an optical device 400 according to various embodiments. The optical device 400 may include a radiation collimator 402, which may be a resonant cavity. The optical device 400 may also include a flat optical element 404, e.g. a metasurface. The resonant cavity 402 may be formed by a front reflector 406, a back reflector 408, and a dielectric or semiconductor spacer 410 separating the front reflector 406 and the back reflector 408. The optical device 400 may further include a plurality of light emitters or sources 412 arranged or located within or inside the spacer 410. The optical device 400 may also include an optical coupler 414, which may be a phase compensating layer. The coupler 414 may be arranged or placed between the metasurface 404 and the cavity 402 to mediate the interactions between the metasurface 404 and the cavity 402.

The device 400 may be or may include a vertical stacked arrangement. As shown in FIG. 4, the spacer 410 may be on the back reflector 408, and the front reflector 406 may be on the spacer 410. The optical coupler 414 may be on the front reflector 406. The metasurface 404 may be over the front reflector 406, i.e. on the optical coupler 414. All these components may be integrated together to properly control light emission of the plurality of light emitters or sources 412.

As highlighted above, the resonant cavity 402 may be formed by the two reflectors (the front reflector 406 and back reflector 408) with a dielectric or semiconductor spacer 410 between them. Light-emitting sources 412, such as quantum wells in light-emitting diodes (LEDs) or other luminescence sources, may be located inside the spacer 410. The thickness of the cavity 402 may be required to be designed properly according to the wavelength of the light-emitting sources 412 in order to satisfy the resonance condition. The device 400 may be a LED with an additional integrated reflector and a metasurface on top.

The back reflector 408 and the front reflector 406 may be used to establish a strong resonance inside the cavity 410 by reflecting light back and forth. The back reflector 408 may be designed to have an extremely high or nearly perfect reflection so that no or little light may propagate through the back reflector 408.

The front reflector 406 may have a relatively lower reflection than the back reflector 408 to allow light to transmit through. The design of the front reflector 406 may be critical to convert the original omni-directional emission from the light emitting sources 412 to directed light (e.g. quasi-plane waves), which can then be manipulated by the metasurface 404.

The metasurface 404 may be used to subsequently modify the directed light (quasi-plane waves) outputted from the front reflector 406. Depending on application requirements, the metasurface 404 may be configured to steer the emission direction of the directed light beams, to control the polarization state of the directed light beams, to focus the directed light beams, or realize other functionalities.

The coupler 414 may be a phase compensating layer. Light impinging on the metasurface 404 may be reflected, and the reflected light beams may interact with the cavity 402, causing undesired effects. The phase compensating layer 414 added to mediate the interactions, so that the reflected light beams from the metasurface may interfere with the cavity 402 constructively. The layer 414 may provide a positive impact on the device performance and may enhance the device efficiency.

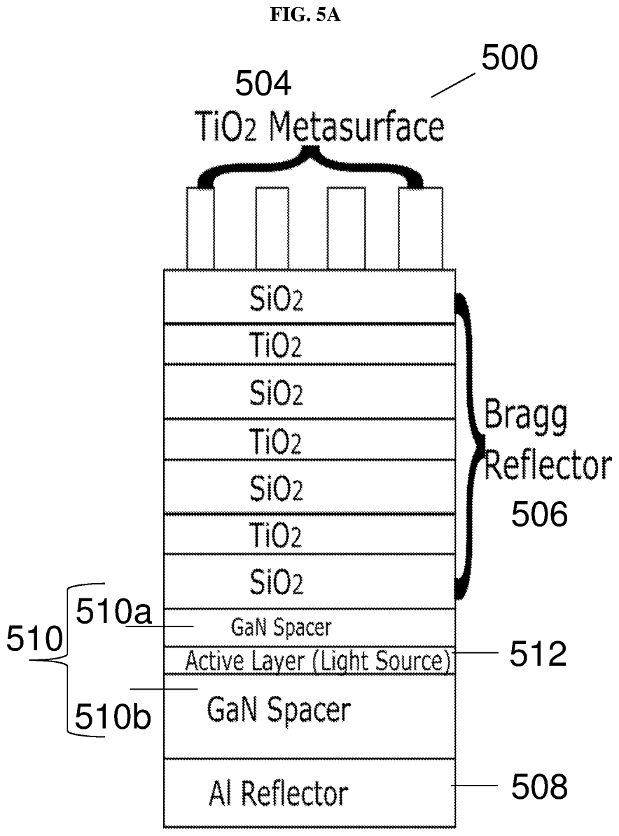

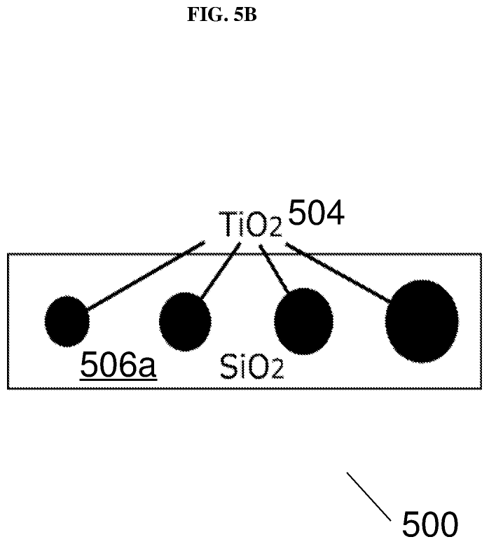

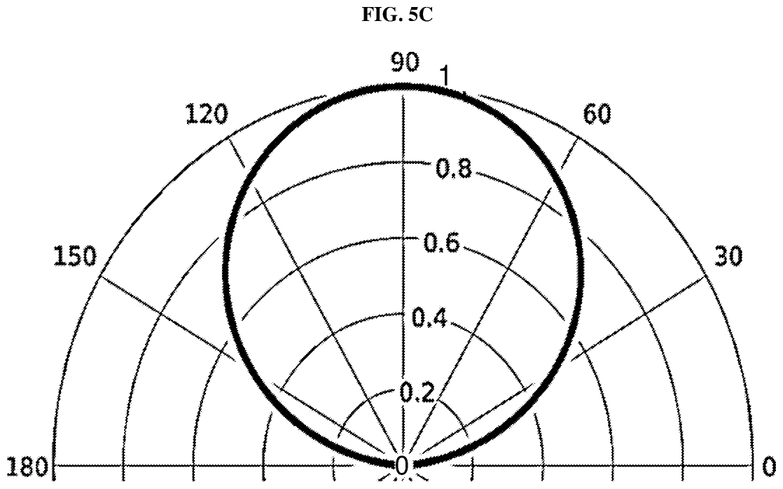

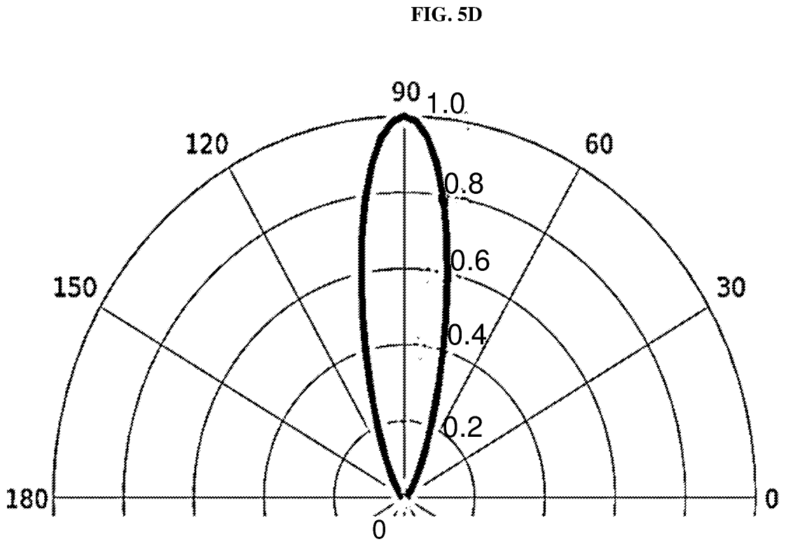

FIG. 5A is a schematic showing a cross-sectional side view of one supercell 500 of an optical device according to various embodiments. FIG. 5B is a schematic showing a top planar view of the super cell 500 of the optical device shown in FIG. 5A according to various embodiments. The supercell 500 may be a periodic super cell.

The optical device may include a gallium nitride (GaN) slab 510 as the cavity spacer. The optical device may include a light emitter 512 such as an active layer (for instance, of a p-n junction of a LED device). The slab 510 may have a first portion 510a above the light emitter 512 and a second portion below the light emitter 510b. The optical device may further include a highly reflective back reflector 508 such as an aluminum (Al) mirror, as well as a partially reflecting front reflector 506, e.g. a Bragg reflector. The Bragg reflectors may include alternate layers of a high refractive index material and a low refractive index material, e.g. alternate layers of silicon oxide (SiO₂) and titanium oxide (TiO₂), alternate layers of silicon oxide (SiO₂) and alumina (Al₂O₃), alternate layers of silicon oxide (SiO₂) and hafnium dioxide (HfO₂), or alternate layers of silicon oxide (SiO₂) and silicon nitride (Si₃N₄).

The optical device may additionally include a highly transparent dielectric metasurface 504 for phase control, specifically designed to deflect normally incident plane waves. The metasurface 504 may be made of titanium oxide (TiO₂) cylinders arranged in periodic supercells. As shown in FIGS. 5A-B, the cylinders may be of different diameters. As the metasurface 504 is highly transparent and the interaction between the metasurface 504 and the cavity is kept at minimum, so no phase compensating layer may be needed. The optical device may work at the GaN LED emission wavelength, namely 460 nm.

As highlighted above, the cavity may be formed by an Al mirror 508 and a Bragg reflector 506 separated by a GaN spacer 510. The Al mirror 508 may be thick enough to block and reflect most of light emitted by the active layer 512. The Bragg reflector 506 may be made of a few alternating layers of TiO₂ and SiO₂, where TiO₂ has the complex refractive index of 2.62+i 0.006 and SiO₂ has the refractive index of 1.5. The Bragg reflector 506 may include 3 layers of TiO₂ and 4 layers of SiO₂. Each layer of TiO₂ or SiO₂ may have the thickness of a quarter wavelength of the light inside the corresponding material. The thickness of each TiO₂ layer may be about 44 nm, and the thickness of each SiO₂ layer may be about 77 nm. The thickness of the GaN spacer 510 may be about 220 nm, the LED active layer 512 may be about 10 nm thick, located about 85 nm below the SiO₂/GaN interface.

The Bragg reflector 506 may have a lower reflectivity (compared to the Al mirror 508), and the Bragg reflector 506 may allow a part of the light to be emitted out of the cavity. The thickness of the GaN spacer 510, which equals to the thickness between the Bragg reflector 506 and the Al mirror 508, may be chosen in such a way that the cavity supports standing waves along the normal direction (the direction normal to the surfaces of the reflectors 506, 508), so the dominant emission from the cavity may be along that direction, i.e. the direction normal to the surfaces of the reflectors 506, 508.

As a consequence, the cavity may convert the omni-directional emission from the active layer 512 to a highly directed light (quasi-plane waves). FIG. 5C shows the emission pattern of the active layer 512 embedded in the bare spacer 510 (i.e. without reflectors and metasurface). FIG. 5C shows that the emission pattern is omni-directional. The emitted wavelength may be at about 460 nm. FIG. 5D shows the emission pattern of the resonant cavity, which include the front reflector 506, the back reflector 508, and the spacer 510 with the embedded active layer 512 of the optical device according to various embodiments (i.e. without metasurface).

FIGS. 5C-D show the light emission into the half space above the front (Bragg) reflector. 90 degrees corresponds to the direction normal to the reflectors. As shown in FIGS. 5C-5D, the light emission of the resonant cavity may be more directed along the main emission direction.

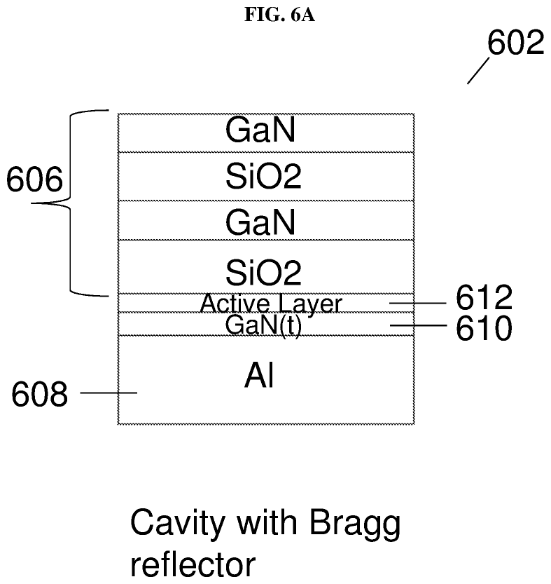

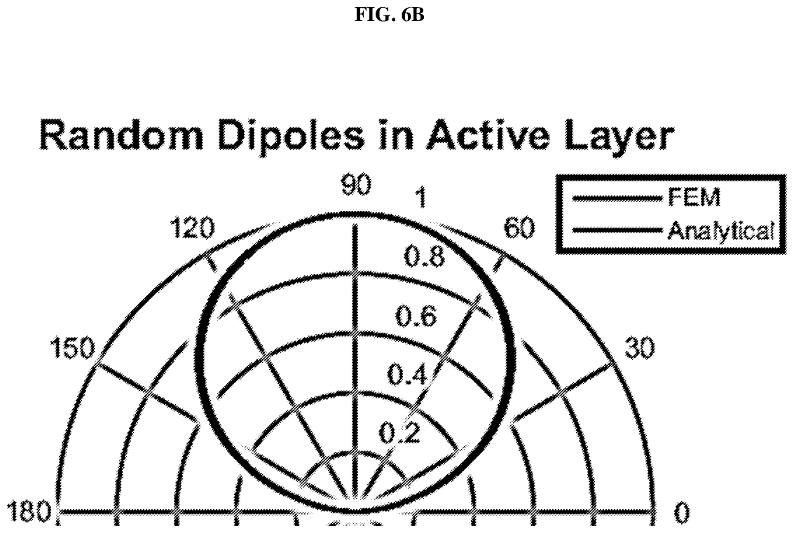

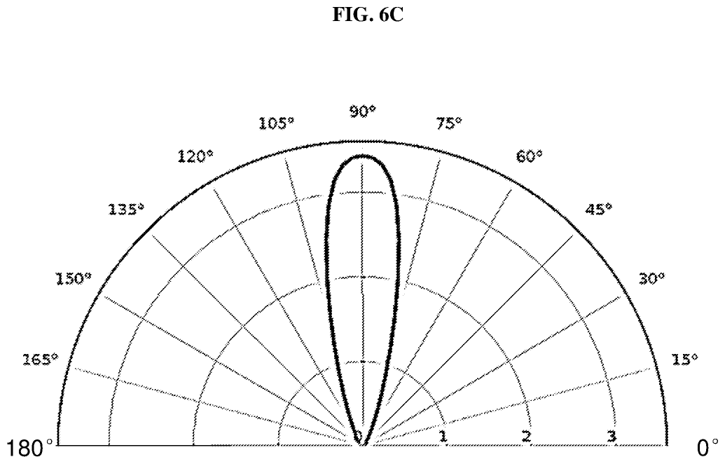

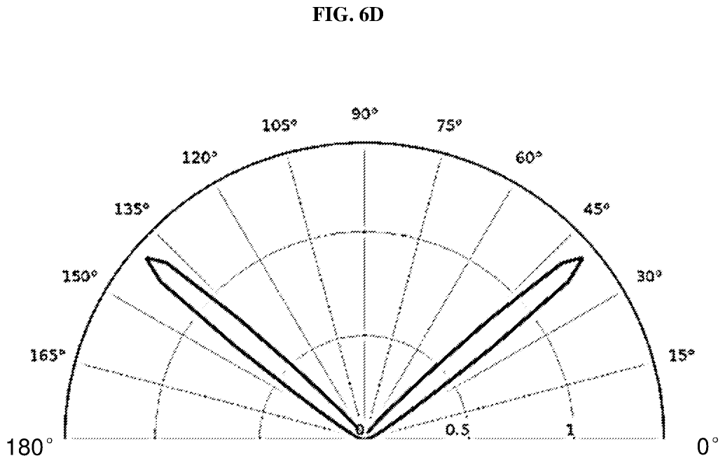

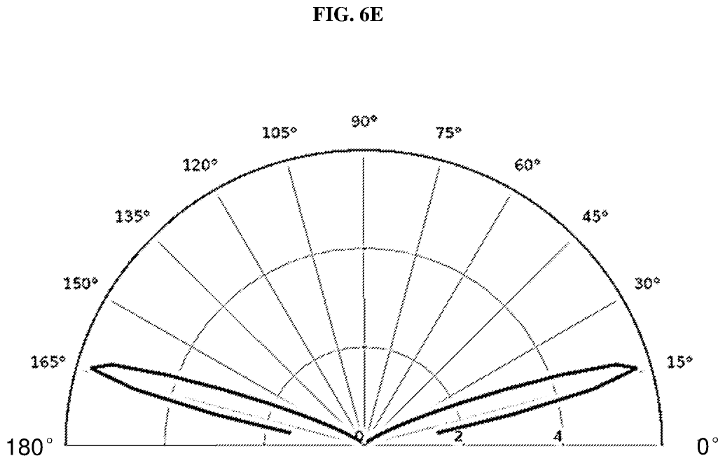

FIG. 6A is a schematic showing a resonant cavity 602 without metasurface according to various embodiments. The resonant cavity 602 may be formed by a Bragg reflector 606 including alternate layers of gallium nitride (GaN) and silicon oxide (SiO₂), an aluminum (Al) back reflector 608, as well as a gallium nitride (GaN) spacer 610 and an active layer 612 between reflectors 606, 608.

FIG. 6B shows emission pattern of the active layer 612 (i.e. without reflectors and metasurface). FIG. 6C shows a possible emission pattern of the resonant cavity without metasurface according to various embodiments. FIG. 6D shows another possible emission pattern of the resonant cavity without metasurface according to various embodiments. FIG. 6E shows yet another possible emission pattern of the resonant cavity without metasurface according to various embodiments. The emission patterns shown in FIGS. 6B-E may be obtained depending on factors such as thickness of each layer in the Bragg reflector 606, the thicknesses of the spacer 610 and the active layer 612, the material of the reflectors 606, 608, the material of the spacer 610, the material of the active layer 612 etc.

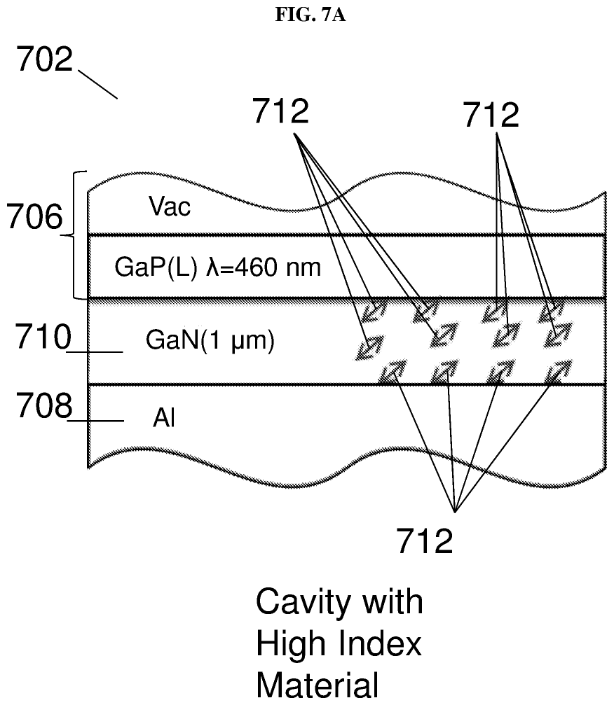

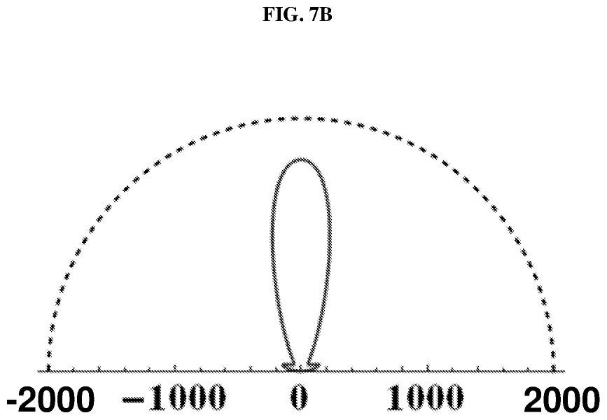

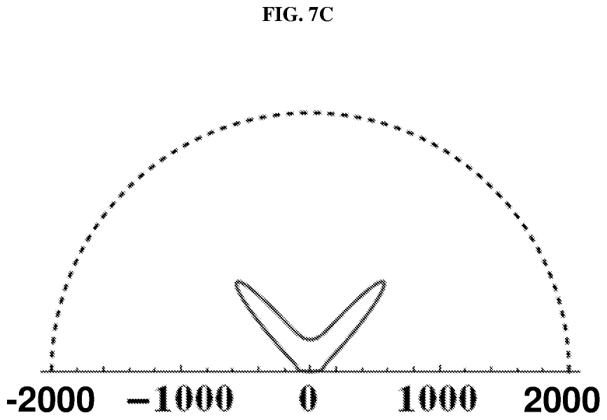

FIG. 7A is a schematic showing a resonant cavity 702 without metasurface according to various embodiments. The resonant cavity 702 may be formed by a top reflector 706 and a bottom reflector 708, as well as a gallium nitride (GaN) spacer 710 with embedded optical emitters 712. The bottom reflector 708 may be an aluminum (Al) reflector, while the top reflector 706 may be a high index reflector including gallium phosphide (GaP) in contact with vacuum (vac).

FIG. 7B shows a possible emission pattern of the resonant cavity without metasurface according to various embodiments. FIG. 7C shows another possible emission pattern of the resonant cavity without metasurface according to various embodiments.

In various embodiments, the metasurface used to steer the directed light emitted from the cavity may include titanium oxide (TiO₂) cylinders arranged periodically. In various embodiments, the metasurface may be designed or configured in such a way that it is highly transparent at the operating wavelength, thus minimizing light feedback into the cavity once it has been emitted. However, in various other embodiments, high transmission may not be a necessary condition for the metasurface to work with a resonant cavity, and any metasurface may be used. The radius of each cylinder may be designed to locally provide specific phase retardation to the incoming light wave. In this way, the phase front profile of any desired output beam may be mapped using cylinders of different radii.

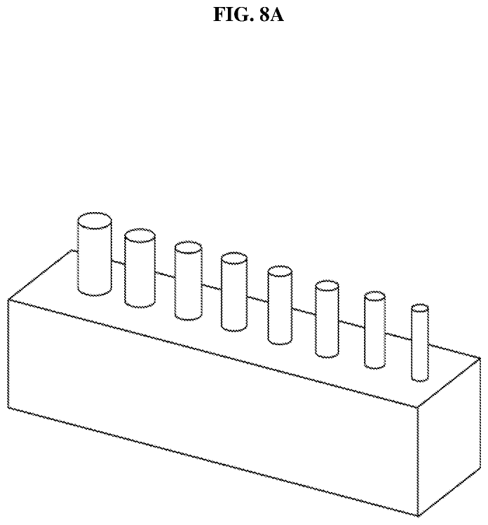

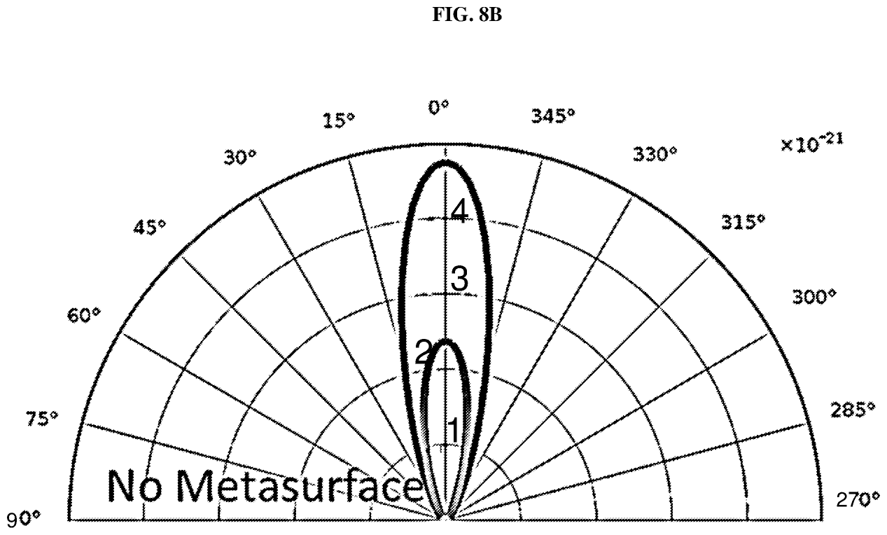

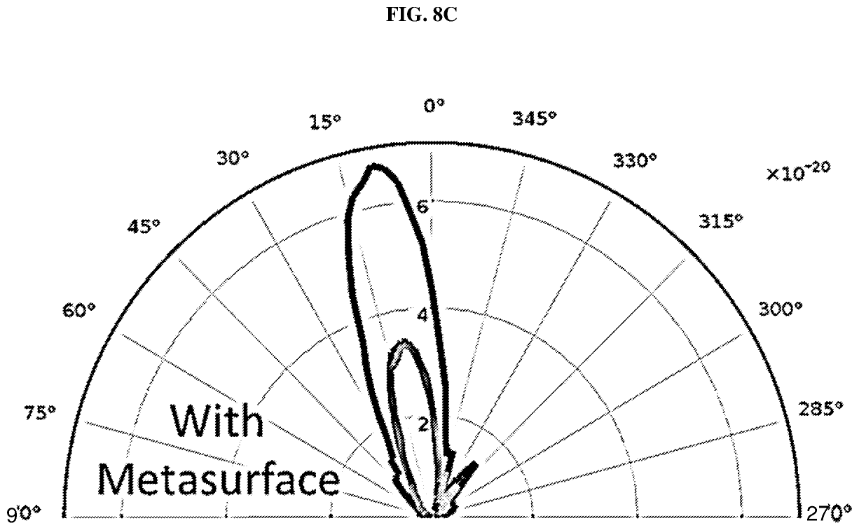

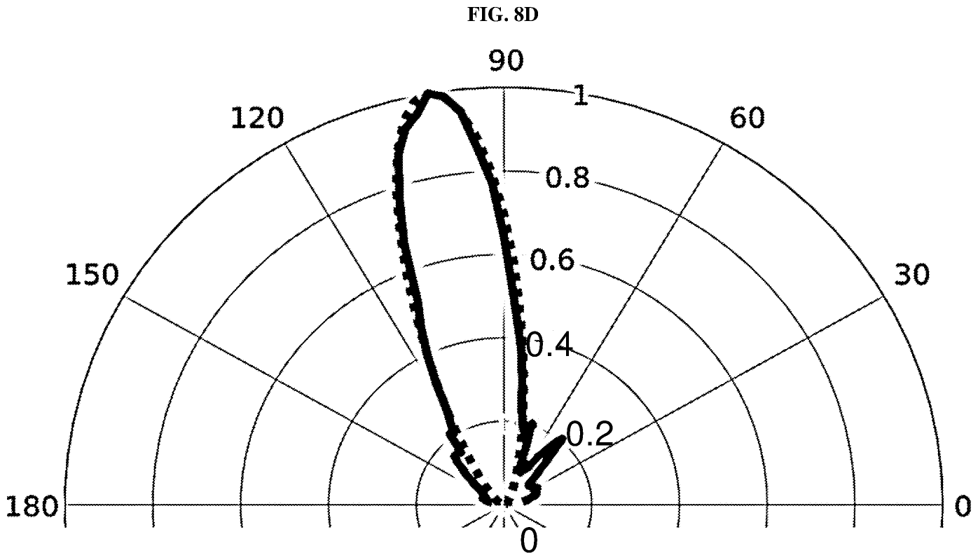

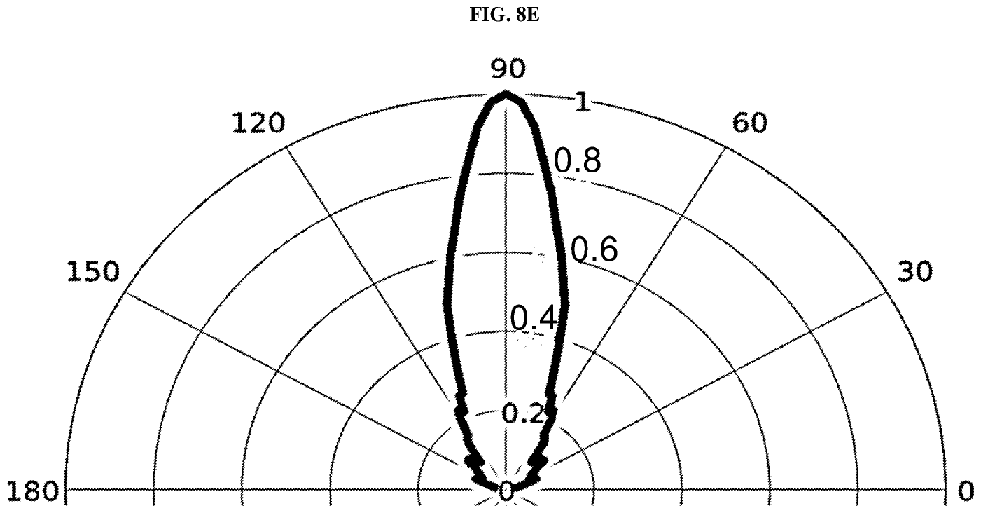

FIG. 8A is a schematic showing a perspective view of a metasurface super cell including 8 titanium oxide (TiO₂) cylinders of the optical device according to various embodiments. In various embodiments, the cylinders may have a height of 460 nm, and may be arranged in a rectangular lattice with center-to-center distances of 300 nm. In various embodiments, the cylinders may be used to deflect plane waves. The phase profile of a deflected light wave may be mapped into a supercell, containing several cells with increasing cylinder diameters along the supercell direction, as shown in FIG. 8A. Under normal plane wave excitation, the metasurface may deflect the transmitted light, and the deflection angle may depend on the total supercell size relative to the wavelength. The efficiency of deflection may depend on the precision of the phase mapping and the reflectivity of the metasurface. Using cylinders that are sub-wavelength in the lateral size (diameter) may allow for a better mapping of the phase (a larger number of elements-per-supercell) and, ultimately, may allow for a higher efficiency. The structures may be further optimized to minimize the metasurface reflectivity, further increasing its efficiency.

FIG. 8B shows the emission pattern of an optical device without a metasurface according to various embodiments. FIG. 8C shows the emission pattern of an optical device having the metasurface with a supercell of 8 cylinders as shown in FIG. 8A according to various embodiments. The 8-cylinders have diameters of 188 nm, 165 nm, 152 nm, 141 nm, 132 nm, 124 nm, 115 nm, and 100 nm.

FIG. 8C clearly shows a deflection from the emission from the cavity alone (see FIG. 5D). The emission is deflected at an angle of 10° with respect to the surface normal.

FIG. 8D shows the emission pattern shown in FIG. 8C of the optical device according to various embodiments compared to the cavity emission pattern (rotated by 10°). The rotated cavity emission pattern is indicated by the dashed line, while the emission pattern of the device with the metasurface is indicated by the continuous line.

FIG. 8E shows the emission pattern of the optical device having the supercell as shown in FIG. 8A according to various embodiments in a plane perpendicular to the super cell.

FIGS. 8D-E show that there is a good match between theory and actual performance. Theory predicts 11 degrees deflection for pure, normally incident, plane waves, which the actual simulation results show a deflection of 10 degrees. FIG. 8E shows that there is only one emission peak, i.e. the one designed for.

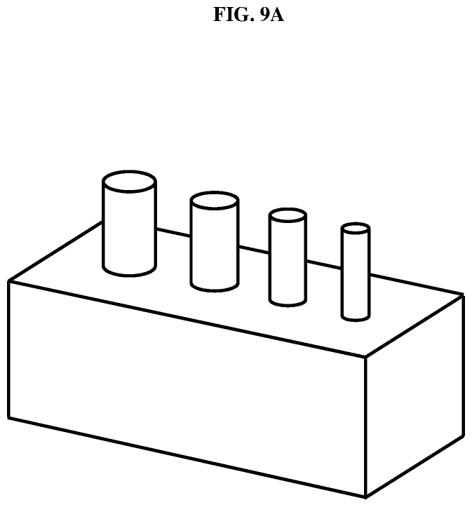

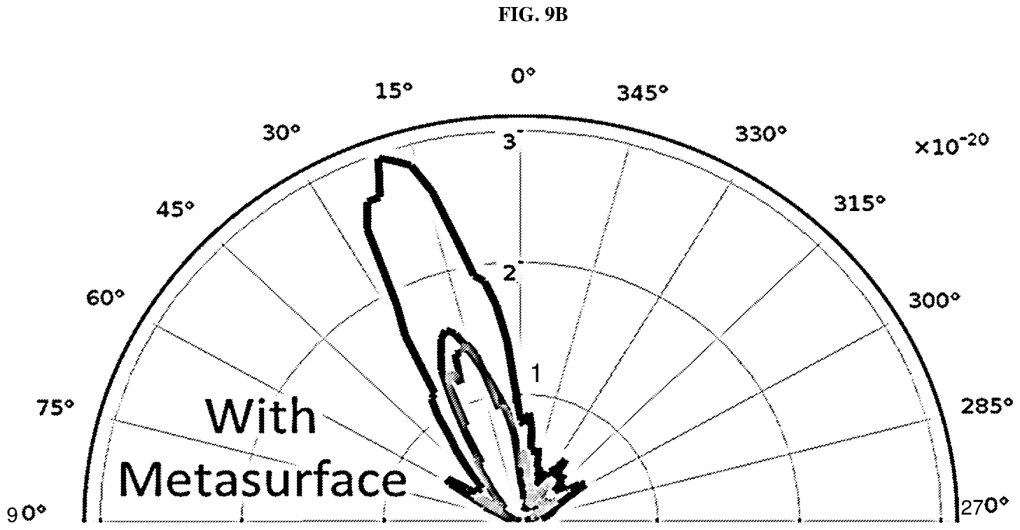

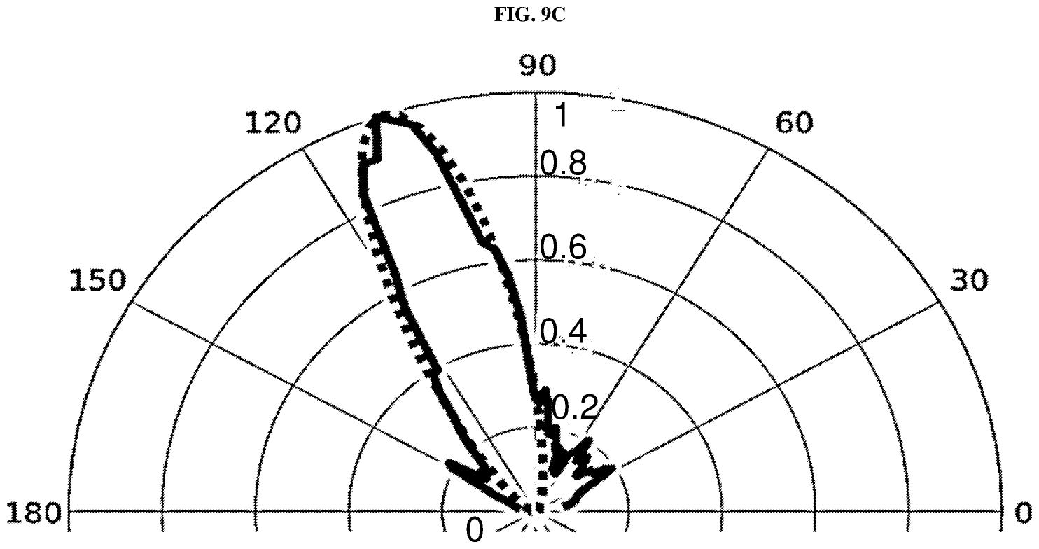

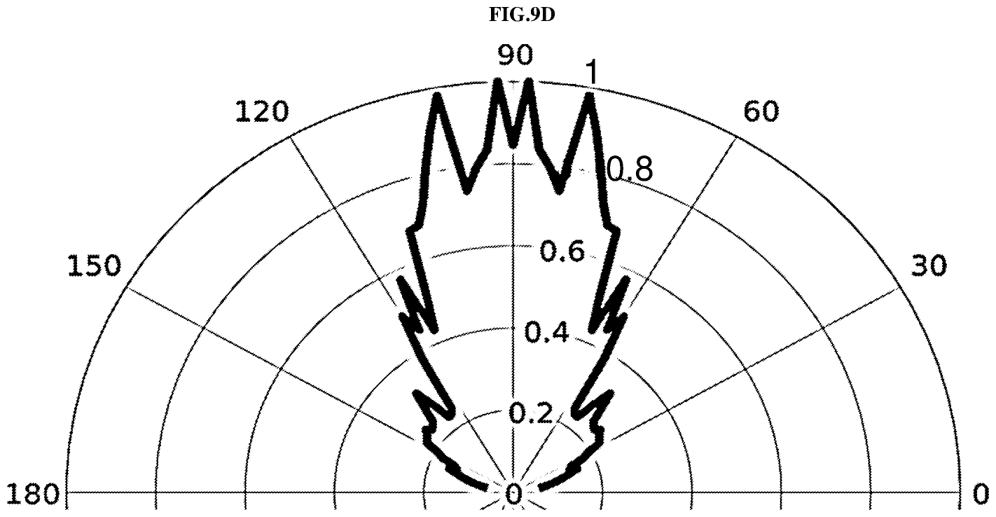

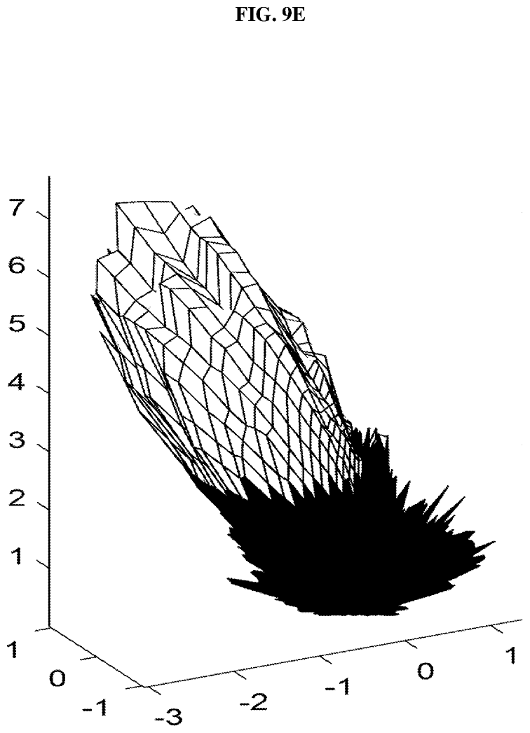

FIG. 9A is a schematic showing a perspective view of a metasurface super cell including 4 titanium oxide (TiO₂) cylinders of the optical device according to various embodiments. The 4-cylinder metasurface has cylinders with diameters of 188 nm, 152 nm, 132 nm, and 115 nm.

FIG. 9B shows the emission pattern of an optical device having the metasurface with a supercell of 4 cylinders as shown in FIG. 9A according to various embodiments.

FIG. 9B also clearly shows a deflection as compared to the emission from the cavity alone (see FIG. 5D). The emission is deflected at an angle of 19° with respect to the surface normal.

FIG. 9C shows the emission pattern shown in FIG. 9B of the optical device according to various embodiments compared to the cavity emission pattern (rotated by 19°). The rotated cavity emission pattern is indicated by the dashed line, while the emission pattern of the device with the metasurface is indicated by the continuous line.

FIG. 9D shows the emission pattern of the optical device having the supercell as shown in FIG. 9A according to various embodiments in a plane perpendicular to the super cell.

FIG. 9E shows a three dimensional emission pattern of the optical device having a supercell as shown in FIG. 9A.

FIGS. 9C-C also show a good match between theory and actual performance. The simulation results show a deflection of 19°, close to the 22 degrees deflection angle predicted for pure, normally incident, plane waves.

FIGS. 9D-9E show the emission pattern in the plane perpendicular to the metasurface supercell and the three-dimensional emission pattern respectively, proving that there is only one major emission peak.

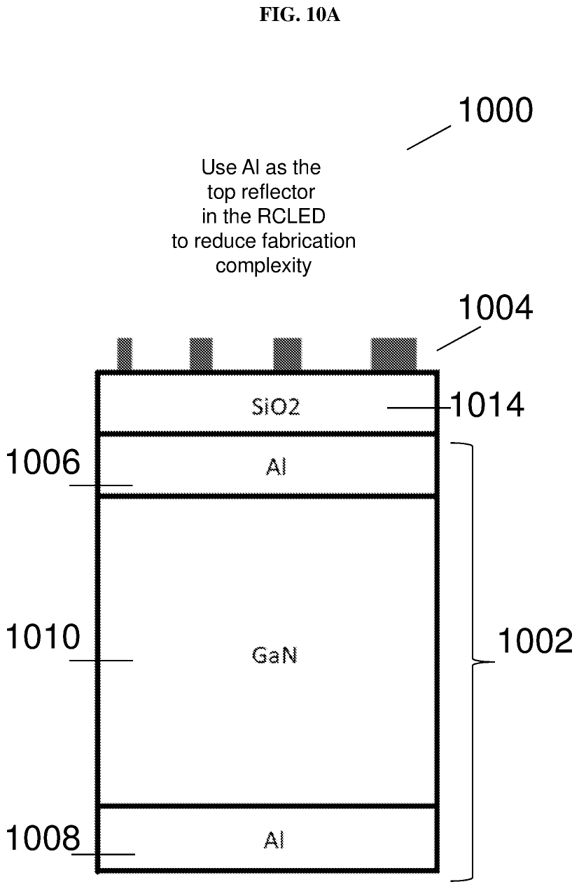

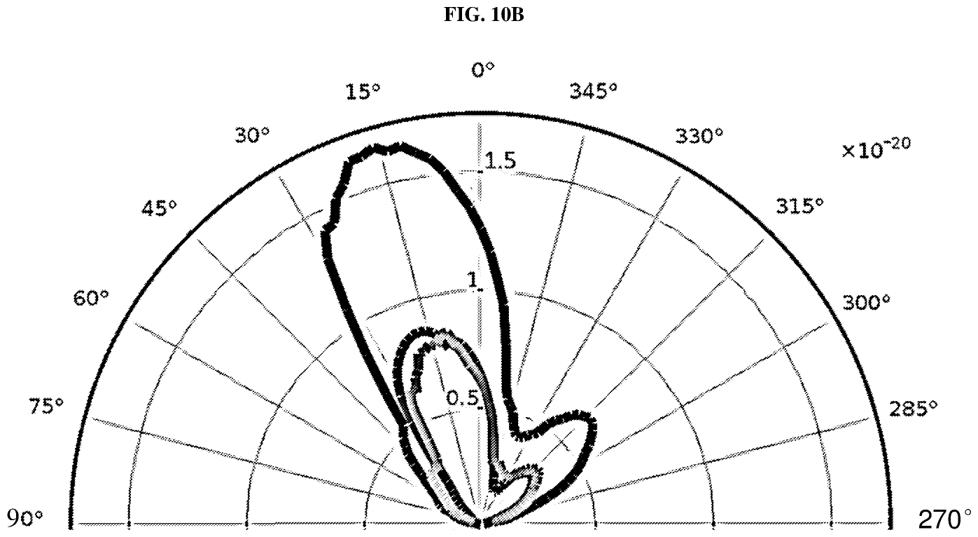

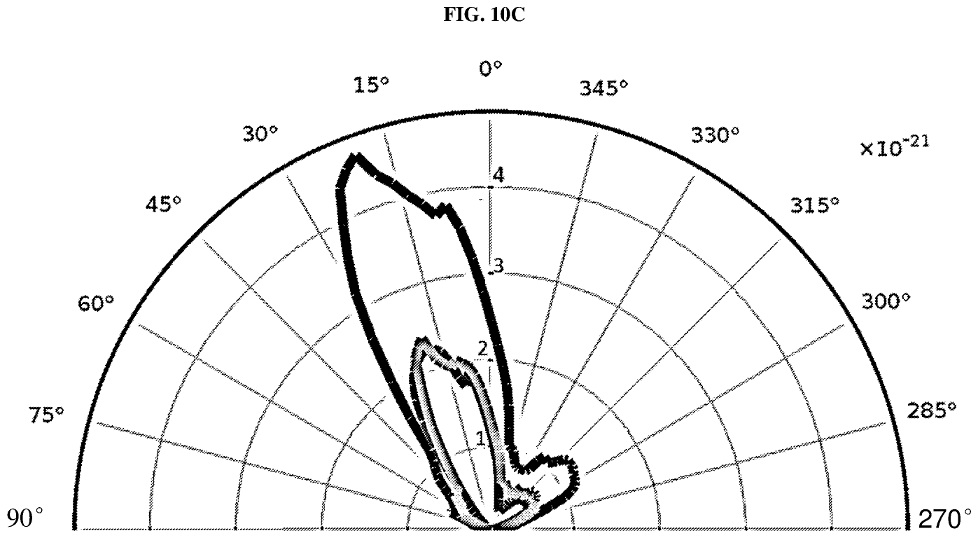

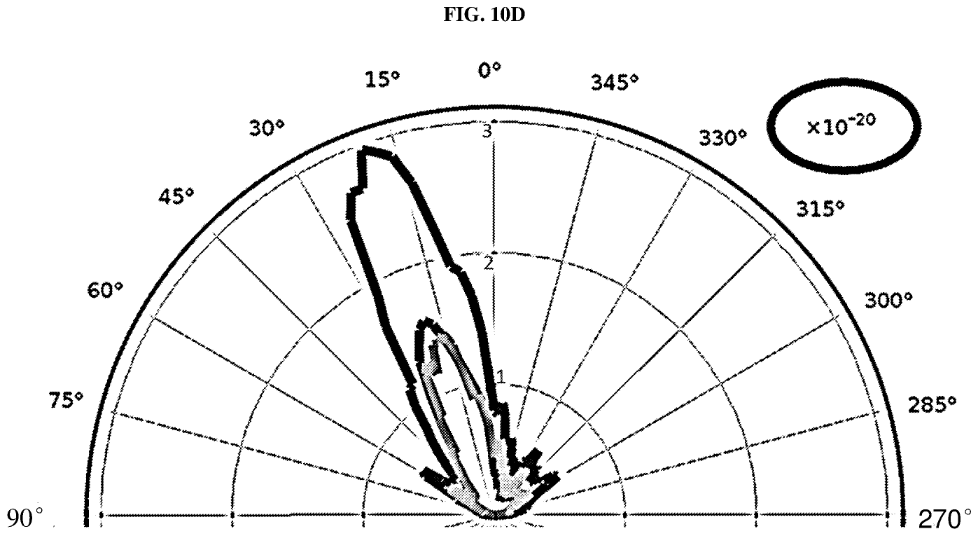

FIG. 10A is a schematic showing a cross-sectional side view of an optical device 1000 according to various embodiments. The device 1000 may include a resonant cavity 1002 formed by aluminum (Al) reflectors, 1006, 1008, as well as a gallium nitride (GaN) spacer 1010 (with embedded emitters, which are not shown in FIG. 10A). The device 1000 may also include an optical coupler 1014 on the top reflector 1006, and a plurality of optical elements forming a metasurface 1004 on the optical coupler.

FIG. 10B shows the emission pattern of the optical device 1000 as shown in FIG. 10A in which the top reflector is 10 nm thick according to various embodiments. FIG. 10C shows the emission pattern of the optical device 1000 as shown in FIG. 10A in which the top reflector is 20 nm thick according to various embodiments. FIG. 10D shows the emission pattern of an optical device with a Bragg reflector as the top reflector according to various embodiments. FIGS. 10B-D show that an aluminum reflector as a top reflector may work. However, a Bragg reflector may have higher efficiency and higher directionality.

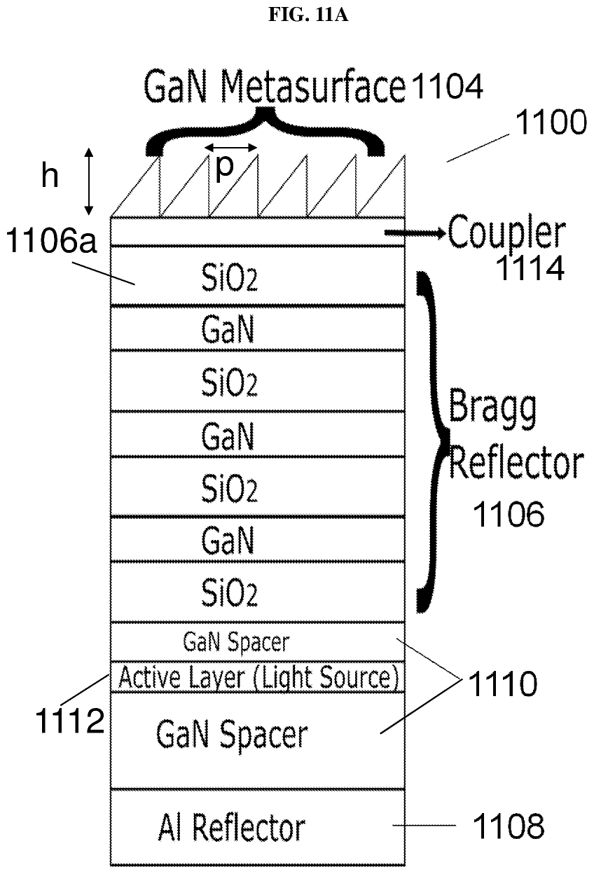

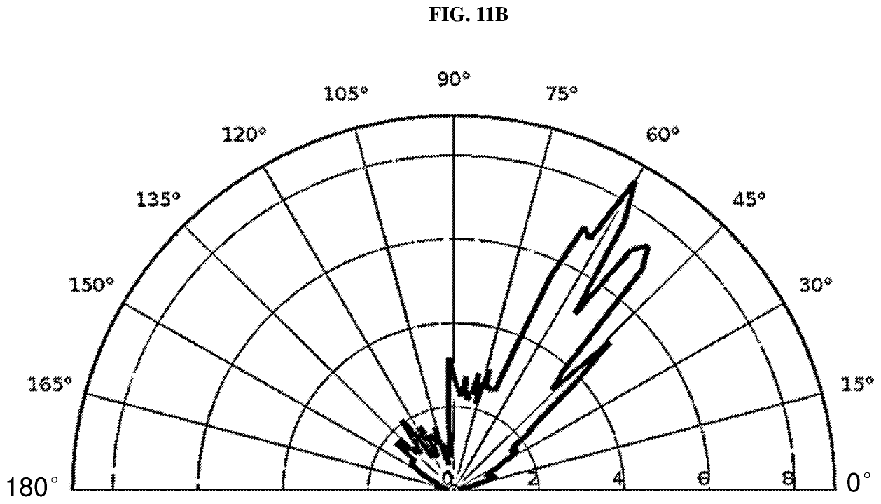

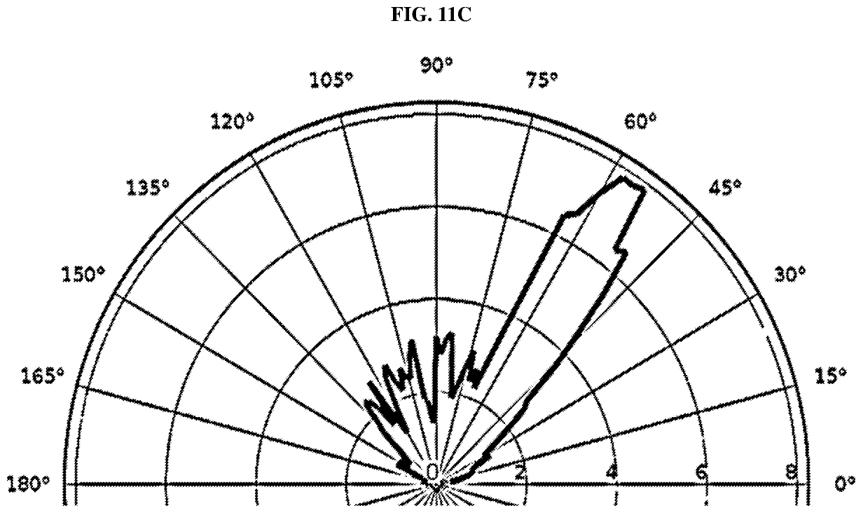

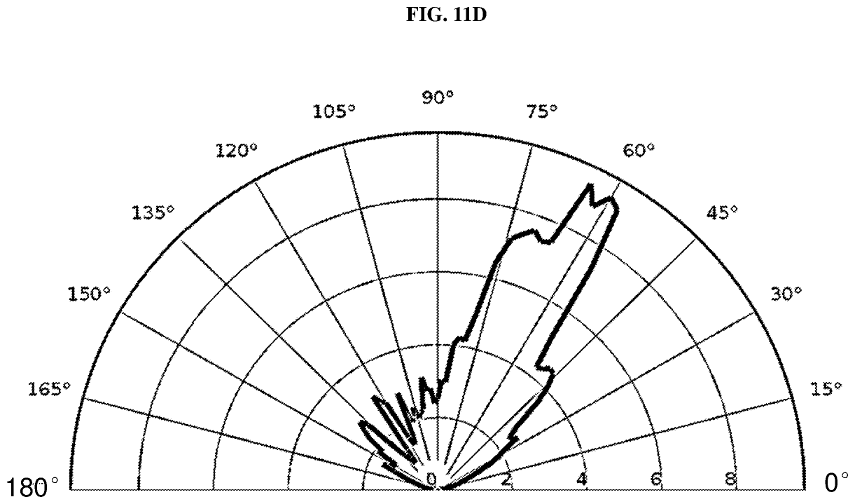

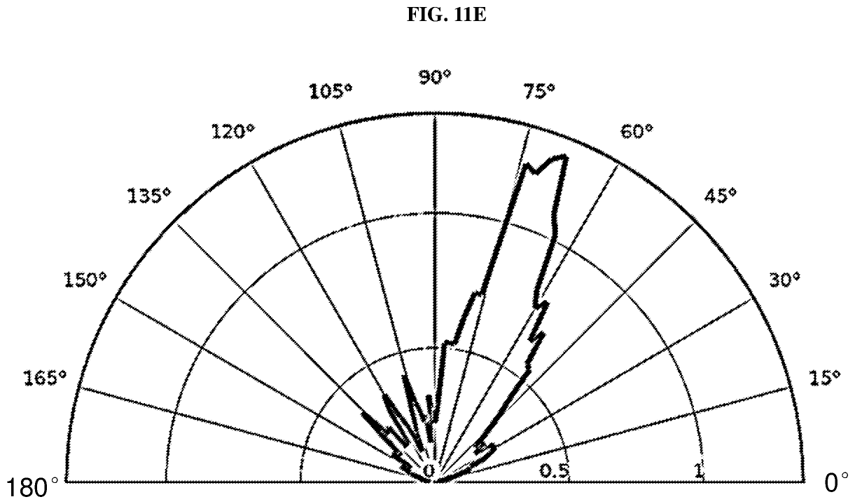

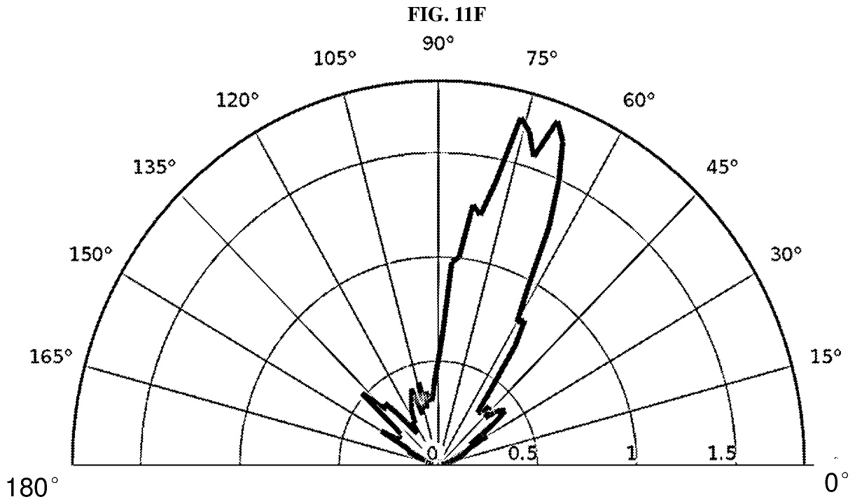

FIG. 11A is a schematic showing a cross-sectional side view of an optical device 1100 according to various embodiments. The optical device 1100 may include a resonant cavity formed by the Bragg reflector 1106 (which may include alternate layers of silicon oxide (SiO₂) and gallium nitride (GaN)), an aluminum (Al) reflector 1108, a GaN spacer 1110, and an active layer 1112 embedded in the spacer 1110. The optical device 1100 may further include a coupler 1114 on the Bragg reflector 1106, and an optical element 1104 such as a blazed grating on the coupler 1114.

As the reflection from the grating 1104 may not be negligible, various embodiments may require the coupler 1114, such as a phase compensating layer or region. In various embodiments, the coupler 1114 may be a portion or region of the top reflector 1106. In various embodiments, the coupler 1114 may include silicon oxide (SiO₂). The coupler 1114 may be continuous with a topmost reflector portion 1106a, and the coupler 1114 may be termed as a phase compensating region. The phase compensating region 1114 may together with the topmost reflector portion 1106a, which may also include silicon oxide, form the top layer of the Bragg reflector 1106.

Therefore, the thickness of the top layer of the Bragg reflector may not be of a quarter wavelength, which is required by the Bragg condition, but may be thicker or thinner than a quarter wavelength.

FIG. 11B shows an emission pattern of an optical device without the phase compensating region according to various embodiments. FIG. 11C shows an emission pattern of the optical device 1100 including the phase compensating region 1114 as shown in FIG. 11A according to various embodiments.

FIGS. 11B-C are based on a value of about 800 nm for the period (p) of the grating 1104, and a value of about 278 nm for the height (h) of the grating 1104. The grating 1104 may give a deflection angle of about 35 degrees. If the device does not include a coupler and simply includes only a Bragg reflector (without the phase compensating region 1114), the emission pattern is as shown in FIG. 11B. As shown in FIG. 11B, the emission peak of around 30 degrees is broken into several small peaks with kinks in between, which may be undesirable for a beam steering device. If the optical device includes a coupler, which may be 130 nm thick SiO₂, then the emission pattern may be as shown in FIG. 11C, where only one strong and solid peak at around the designed 35 degree is present.

FIG. 11D shows another emission pattern of the device 1100 including the phase compensating region 1114 as shown in FIG. 11A according to various embodiments. FIG. 11D is based on a value of about 1000 nm for the period (p) of the grating 1104, and a value of about 291 nm for the height (h) of the grating 1104.

FIG. 11E shows yet another emission pattern of the device 1100 including the phase compensating region 1114 as shown in FIG. 11A according to various embodiments. FIG. 11E is based on a value of about 1200 nm for the period (p) of the grating 1104, and a value of about 297 nm for the height (h) of the grating 1104.

FIG. 11F shows yet another emission pattern of the device 1100 including the phase compensating region 1114 as shown in FIG. 11A according to various embodiments. FIG. 11F is based on a value of about 1500 nm for the period (p) of the grating 1104, and a value of about 297 nm for the height (h) of the grating 1104.

Any metasurface may work with a cavity. Some adjustments of the design parameters of the cavity may be required.

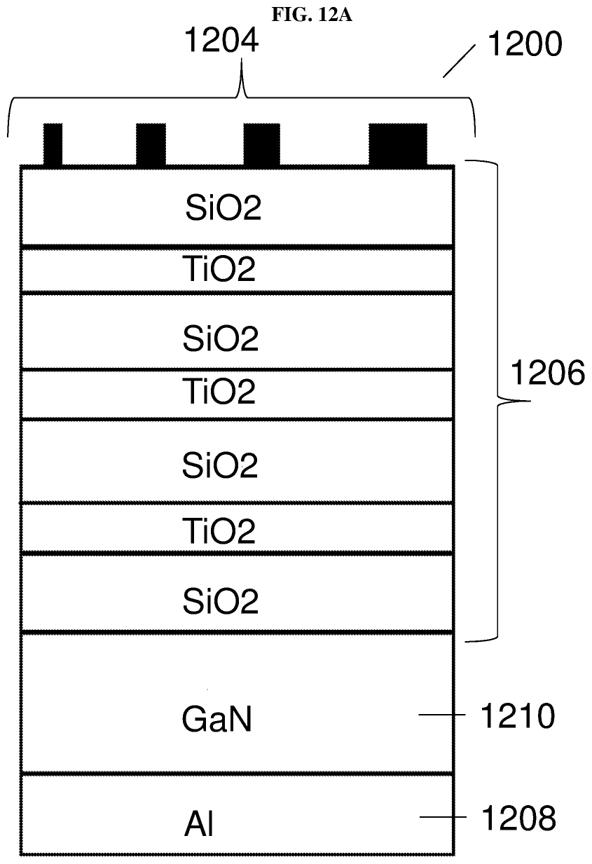

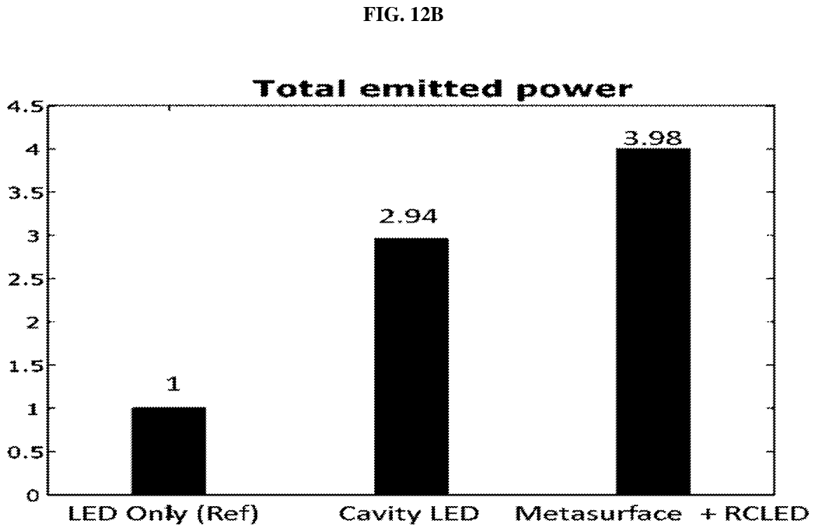

FIG. 12A is a schematic showing a cross-sectional side view of an optical device 1200 according to various embodiments. The device 1200 may include a Bragg reflector 1206 (including alternate layers of silicon oxide (SiO₂) and titanium oxide (TiO₂)), an aluminum (Al) reflector 1208, and a gallium nitride (GaN) spacer 1210 between the reflectors 1206, 1208. The device 1200 may further include a 4-disk metasurface 1204 on the Bragg reflector 1206. The device 1200 may combine the 4-disk metasurface 1204 with a resonant cavity light emitting diode (RCLED).

FIG. 12B is a diagram comparing the total emitted power of a light emitting diode (LED), a cavity light emitting diode (LED), and an optical device as shown in FIG. 12A according to various embodiments. FIG. 12B shows that the optical device may improve extraction efficiency by about 4 times.

Various embodiments may have many different metasurface designs to realize different functionalities. Various embodiments may be used for controlling emission deflection. Various embodiments may be used in polarizers, lenses, axicons, holography, or optical vortexes etc.

In various embodiments, the flat optical element(s) may include resonant or non-resonant elements that may have sub- or super-wavelength sizes, such as blazed or ‘echellete’ gratings, binary blazed gratings, asymmetric diffractive gratings or phased array antennas (either metallic or dielectric).

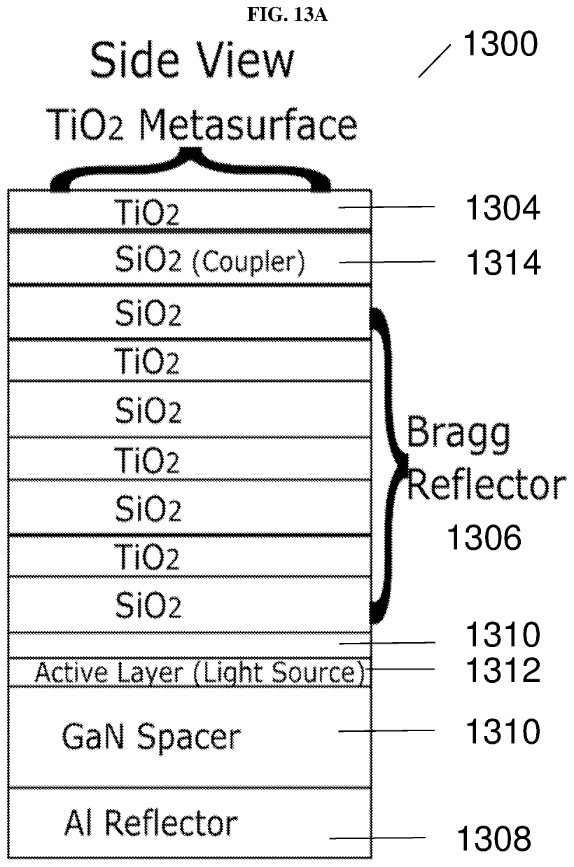

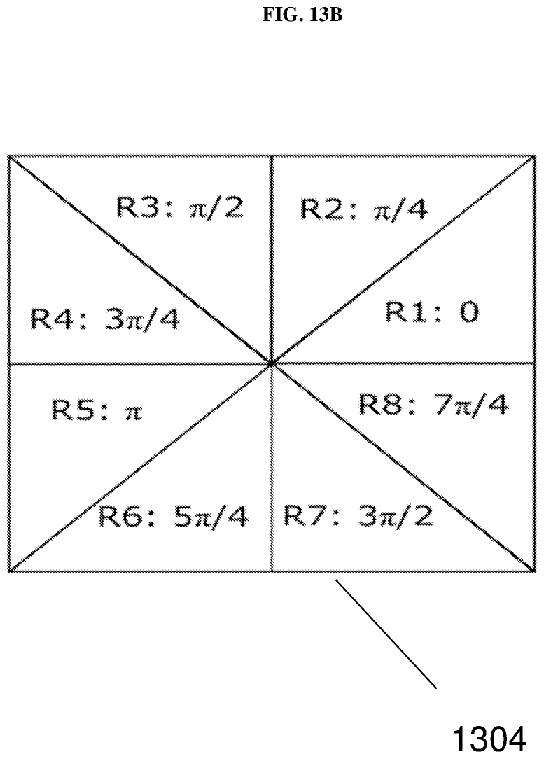

FIG. 13A is a schematic showing a cross-sectional side view of an optical device 1300 according to various embodiments. The optical device 1300 may be an optical vortex. FIG. 13B is a schematic showing a top planar view of the optical device 1300 shown in FIG. 13A according to various embodiments. The optical device 1300 may include a resonant cavity formed by a Bragg reflector 1306, an aluminum (Al) reflector 1308, and a gallium nitride (GaN) spacer 1310 between reflectors 1306, 1308 including an active layer 1312. As shown in FIG. 13A, the Bragg reflector 1306 may include alternate layers of titanium oxide (TiO₂) and silicon oxide (SiO₂). The device 1300 may include a coupler 1314, which may be a layer of SiO₂ acting as a phase compensating layer, on the Bragg reflector 1306. The device 1300 may also include a flat optical element 1304, which may include TiO₂. As shown in FIG. 13B, the flat optical element 1304 may provide phase manipulation to the directed light beam generated by the resonant cavity.

In many cases, the desired functionality may be achieved by phase manipulation (as the case for device 1300), amplitude manipulation, or polarization manipulation. Various embodiments may be applied to perform the desired functionality with all types of omnidirectional random light sources, provided that the specific flat optical element or elements work for an incident plane wave generated by the resonant cavity that converts the omnidirectional random light(s) into more directed light(s).

Both reflectors 1306, 1308 may be varied or changed for device 1300. For example, the front reflector 1306 may include an additional Bragg reflector (which may or may not be different from the back reflector 1308), or replaced with a high-index material (such as semiconductors), provided the index is much larger than that of the spacer 1310, or a metal. The back reflector 1308 may be replaced with another Bragg reflector, in which the reflectivity may be controlled by the number of layers, and may achieve very high values if the number of layers is large enough. In these cases, the emission may still be upwards, and the device 1300 may still work. In other embodiments the metasurface may be on the side of the back reflector, or even in both sides of the cavity (being the same type of metasurface or different types of metasurfaces on each side).

In various embodiments, the radiation collimator may also be achieved using a variety of systems including, but not limited to, omnidirectional reflectors showing angular selectivity (these are layered structures that show high reflectivity over a broad range of angles and low reflectivity for certain small angle ranges, which may include normal incidence), photonic crystal structures with angle-engineered selective band gaps, or artificial effective media showing zero index of refraction (through vanishing effective electric permittivity and magnetic permeability), two-dimensional materials (such as graphene), topological insulators, transformational optical elements. The advantages of the cavity design as described herein includes its simplicity and, its ability to enhance the emission rate of light sources contained in it.

In various embodiments, a GaN LED may be included as the light-emitting source. However, other kind of LEDs (including but not limited to those based on GaP, InP, GaAs) as well as any random light emitters may also be used, such as quantum dots or luminescent molecules of different excitation nature (including but not limited to electroluminescence, photoluminescence, incandescence, chemiluminescence, sonoluminescence, and mechanoluminescence). The random light emission may be converted to directional light beams or quasi-plane waves by the radiation collimator, and subsequently manipulated by the metasurface to obtain the desired functionalities. In various embodiments, light emitters may be located inside the radiation collimator. In various other embodiments, the light emitters may be located outside of the radiation collimator. In the case of light sources located outside of the radiation collimator, the light emitters may be located either on the same side or on the opposite side of the flat optical element(s).

Various embodiments may resolve a fundamental conflict: flat optical components, such as metasurfaces, and phase/amplitude/polarization masks only work for directed light (plane waves) or localized sources with known positions, while light emitted by an LED and many other light sources randomly generate light over extended spatial areas, and are omnidirectional. The combination of a radiation collimator (realized, e.g., with a cavity) that converts the omnidirectional emission into directed light (quasi-plane waves), and then feeds the directed light to the flat optical element for further processing may allow bridging of that gap to obtain any desired beam output from light sources that are random and are omnidirectional.

Various embodiments may include a radiation collimator that converts the omnidirectional emission to directed light (quasi-plane waves), and a flat optical component or element for functionality. The collimator and the flat optical element may be tightly integrated. In various embodiments, the flat optical element and the collimator may be two separate parts. The flat optical element and the collimator may be independently designed and optimized. Various embodiments may require a coupler (for phase compensation) for the optical element and the collimator to work together. The phase compensating coupler may be implemented easily. The coupler may not only mediate the interaction, but may also turn the interaction into positive feedback that improves the overall efficiency.

In various embodiments, the front reflector may reduce the interference between the metasurface and the cavity. The front reflector may serve as a spacer to separate the metasurface and the cavity, which minimizes the effect of reflection due to the metasurface on the resonant field inside the cavity. Less interference between the metasurface and the cavity may lead to a more controlled emission.

In various embodiments, the flat optical component may be a metasurface for beam steering. In various embodiments, the metasurface may post-process the directed light (quasi-plane waves) coming out of the top reflector for different functionalities. The metasurface may be designed to steer light to a certain angle, e.g. a 4-cylinder supercell metasurface may rotate the LED emission by 19 degree, while a 8-cylinder supercell metasurface may rotate light by 11 degree. Other functionalities (e.g. focusing lens, polarizer, etc.) can also be realized by placing a suitable metasurface on top of the front reflector.

In various embodiments, the collimator may be a resonant cavity. In various other embodiments, the collimator may include photonic crystals, zero index materials, two-dimensional (2-D) materials (such as graphene), or transformational optical elements. In various other embodiments, the flat optical component may include photonic crystals, zero index materials, 2-D materials (such as graphene), or transformational optical elements.

Various embodiments may offer a lot of design flexibility. By designing the light source, the back and front reflectors and the metasurface, various embodiments may be able to satisfy different requirements of various applications.

Applications may include high-end applications such as aerospace and satellite communication systems owing to the small and light-weight planar structures, or high-power LED output such as an array of phase controlled LEDs. The planar structures may enable mass fabrication.

Various embodiments may be desired by LED manufacturers and designers, or optical system designers.

Photonic Crystals for Omnidirectional Light Emission Control.

Photonic crystals, which are periodic wavelength-scale structures, were employed to enhance the extraction of light or to control its spectral emission and directionality. The method relies on suppression of the number of confined modes of the active layer or radiation modes of certain frequencies. The structures used to manipulate light are wavelength-scale and periodic.

In contrast, various embodiments may be based of subwavelength control of light and may transform undirected emitted light into any desired wavefront.

Resonant-Cavity LEDs and Vertical-Cavity Surface-Emitting Lasers (VCSELs)

An efficient way to enhance light emission and directionality from LED sources relies on encapsulating the light emitting layer within a cavity, forming devices that are usually called resonant-cavity LEDs. While several cavity designs have been proposed, generally they consist of two reflectors with specifically designed reflectivities and separation distance, following a set of design rules. Since the first proposals, devices based both on metallic and dielectric (Bragg) reflectors have been employed, resulting in different performances in terms of total emission enhancement and directionality control.

In contrast, various embodiments may allow generation of arbitrary beam profiles at the output of the device, rather than simply collimating or directing emission.

A particular case of cavity-emitting devices is called vertical-cavity surface-emitting lasers (VCSELs), in which the active region is also embedded inside a cavity and the output radiation can be strongly directional. For this kind of devices, and given the coherence of the light generated as a consequence of the lasing action (that naturally selects light generation through the cavity modes), metasurfaces have been included in some designs (typically substituting one of the reflectors in the cavity), allowing implementation of certain functionalities.

In contrast, various embodiments allow control of incoherently, randomly emitted light.

Metasurfaces for Omnidirectional Light Emission Control

A speckle image holography metasurface was employed to enhance the extraction of light from organic LEDs. The method is based on release of the trapped energy flowing inside the active layer. The metasurface manipulates light by transforming undirected emission into other undirected light.

In contrast, various embodiments may transform undirected light into directed light.

Various embodiments may be used in LED light steering, LED optical vortexes, LED holography or LED polarizers.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An optical device comprising:
a radiation collimator configured to generate a directed light beam based on omni-directional light emission; and
one or more optical elements configured to change a parameter of the directed light beam.

2. The optical device according to claim 1, further comprising:
an optical coupler configured to couple the directed light beam to the one or more optical elements.

3. The optical device according to claim 2,
wherein the optical coupler is further configured to adjust a phase of the directed light beam.

4. The optical device according to claim 1,
wherein the radiation collimator comprises:
a first reflector;
a second reflector; and
a spacer between the first reflector and the second reflector;
wherein the first reflector, the second reflector, and the spacer form a resonant cavity.

5. The optical device according to claim 4,
wherein the first reflector is configured to allow at least a portion of the directed light beam to pass through to the one or more optical elements.

6. The optical device according to claim 4,
wherein the first reflector is a Bragg reflector.

7. The optical device according to claim 4,
wherein the second reflector is a metal reflector or a Bragg reflector.

8. The optical device according to claim 4,
wherein the spacer comprises a semiconductor or a dielectric.

9. The optical device according to claim 4, further comprising:
one or more light emitters configured to generate the omni-directional light emission;
wherein the one or more light emitters are within the spacer.

10. The optical device according to claim 1,
wherein the parameter of the directed light beam is a direction of the directed light beam.

11. The optical device according to claim 1,
wherein the parameter of the directed light beam is an amplitude of the directed light beam.

12. The optical device according to claim 1,
wherein the parameter of the directed light beam is a phase of the directed light beam.

13. The optical device according to claim 1,
wherein the parameter of the directed light beam is a polarization of the directed light beam.

14. The optical device according to claim 1
wherein the one or more optical elements form a metasurface.

15. The optical device according to claim 1,
wherein the one or more optical elements are microstructures or nanostructures.

16. A method of forming an optical device, the method comprising:
forming a radiation collimator configured to generate a directed light beam based on omni-directional light emission; and
forming one or more optical elements configured to change a parameter of the directed light beam.

17. The method according to claim 16, further comprising:
forming an optical coupler configured to couple the directed light beam to the one or more optical elements.

18. The method according to claim 16,
wherein the radiation collimator comprises:
a first reflector;
a second reflector; and
a spacer between the first reflector and the second reflector;
wherein the first reflector, the second reflector, and the spacer form a resonant cavity.

19. The method according to claim 18, further comprising:
forming one or more light emitters within the spacer, the one or more light emitters configured to generate the omni-directional light emission.

20. The method according to claim 16,
wherein the one or more optical elements form a metasurface.
